(19) United States
(12) Patent Application Publication
(10) Pub. No.: US 2014/0251210 A1
(43) Pub. Date: Sep. 11, 2014

(54) MASK STRUCTURE, MASK ASSEMBLY INCLUDING THE SAME, AND MASK STRUCTURE MANUFACTURING METHOD

(71) Applicant: Samsung Display Co., Ltd., Yongin-City (KR)

(72) Inventor: Jae-Hoon JUNG, Yongin-City (KR)

(21) Appl. No.: 14/027,168

(22) Filed: Sep. 14, 2013

(30) Foreign Application Priority Data
Mar. 6, 2013 (KR) 10-2013-0023996

(51) Int. Cl. H01L 51/56

(52) U.S. Cl. CPC H01L 51/56
USPC 118/504; 29/428

(57) ABSTRACT

Disclosed is a mask structure including a body member in which an opening is formed, and a plurality of unit masks disposed in parallel in the opening and separated from each other by a predetermined distance. The mask structure using a plurality of unit masks reduces generation of sagging caused by self-gravitation compared to a mask configured with a conventional single member, thereby preventing generation of a shadow phenomenon caused by a gap between the mask structure and the substrate. Hence, the pixel is formed at an accurate position on the substrate.

### CLAIM OF PRIORITY

This application claims priority to and the benefit of Korean Patent Application No. 10-2013-0023996 filed in the Korean Intellectual Property Office on Mar. 6, 2013, the entire contents of which are incorporated herein by reference.

### BACKGROUND OF THE INVENTION

1. Field of the Invention

The present invention relates to a mask structure, a mask assembly including the same, and a mask structure manufacturing method. More particularly, the present invention relates to a mask structure used for forming a pattern on a substrate, a mask assembly including the same, and a mask structure manufacturing method.

2. Description of the Related Art

In general, substrates used for a process of manufacturing mobile display devices, computer monitors, and organic light emitting diode (OLED) lighting fixtures have been widened. For example, 6, 8, or 18 inches display products are manufactured on the 8th generation substrate having a size of 2200 mm×2500 mm. Wide substrates are used to manufacture a desired number of display panel products at once, and they are more preferred because of various configuration freedoms and a reduction in entire production cost.

The substrate and a mask must be enlarged to manufacture a plurality of display panel products on the wide substrate through a deposition process. However, as the mask is enlarged, its center sags by self-gravitation of the substrate and the mask, and a gap is generated between the mask and the substrate in a peripheral portion. It is difficult to form a pixel with an accurate shape on the substrate because of the gap.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a mask structure for preventing generation of sagging, a mask assembly including the same, and a mask structure manufacturing method.

An exemplary embodiment of the present invention provides a mask structure including: a body member in which an opening is formed; and a plurality of unit masks disposed in parallel in the opening and separated from each other by a predetermined distance.

Penetration portions are formed in the unit masks, and the unit masks are separately disposed by a width of the penetration portions.

The unit masks are formed with a plate-type stick shape and are disposed to cross the body member.

The penetration portions of the unit masks are formed to have a size that corresponds to a sub-pixel of a display device.

Another embodiment of the present invention provides a mask assembly including a frame member on which a plurality of receivers are formed and a mask structure disposed in the receivers. The mask structure includes a body member in which an opening is formed; and a plurality of unit masks disposed in parallel in the opening and separated from each other by a predetermined distance.

Another embodiment of the present invention provides a method for manufacturing a mask structure, including: providing a body member; providing unit masks; and separating the unit masks by a predetermined distance and disposing the unit masks in parallel in an opening of the body member.

The providing the unit masks includes forming penetration portions in the unit masks, and the separating the unit masks by a predetermined distance includes separating the unit masks by a distance that is the same as the width of the penetration portion.

The forming penetration portions in the unit masks includes forming the penetration portions with a size that corresponds to the sub-pixel of a display device.

According to the embodiment of the present invention, the mask structure using a plurality of unit masks reduces generation of sagging caused by self-gravitation compared to a mask configured with a conventional single member, thereby preventing generation of a shadow phenomenon caused by a gap between the mask structure and the substrate. Hence, the pixel is formed at an accurate position on the substrate.

Further, regarding the mask structure, the unit masks are separated by the width of the penetration portion corresponding to the size of the pixel so overlapping of a pixel over an adjacent pixel is prevented when the pixel is deposited on the substrate.

In addition, an organic material can be deposited on the surface of the substrate that is larger than the conventional substrate by using the mask assembly, and a greater quantity of panels can be produced per predetermined time frame, thereby improving productivity.

### BRIEF DESCRIPTION OF THE DRAWINGS

FIG. 1 shows a perspective view of a mask structure according to an exemplary embodiment of the present invention.

FIG. 2 shows a state in which a pixel is formed by a unit mask shown in FIG. 1.

FIG. 3 shows a cross-sectional view of a state in which a pixel is formed by a unit mask shown in FIG. 2.

FIG. 4 shows a perspective view of a mask assembly according to an exemplary embodiment of the present invention.

FIG. 5 shows a flowchart of a method for manufacturing a mask assembly according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. The drawings and description are to be regarded as illustrative in nature and not restrictive. Like reference numerals designate like elements throughout the specification.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise” and variations such as “comprises” or “comprising” will be understood to imply the inclusion of stated elements but not the exclusion of any other elements.

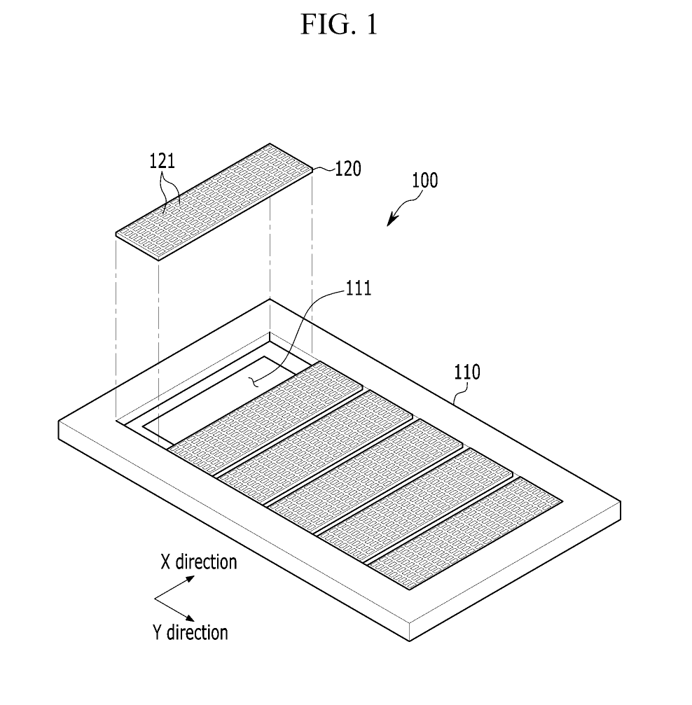

FIG. 1 shows a perspective view of a mask structure according to an exemplary embodiment of the present invention.

Referring to FIG. 1, the mask structure 100 includes a body member 110 and a plurality of unit masks 120.

An opening 111 is formed in the body member 110. A lead-in portion is formed in the body member 110. The lead-in portion is formed to be led in to a bottom from a top of the body member 110 with a predetermined depth along an edge of the opening 111. An end of the unit mask 120 can be combined into the lead-in portion.

It is desirable to form the body member 110 with a metal having excellent rigidity so as to minimize deformation of the unit mask 120 caused by welding when the unit mask 120 is combined to the body member 110 through welding and prevent deformation of the unit mask 120 caused by self-gravitation.

The unit masks 120 are disposed in parallel in the opening 111. The unit masks 120 are disposed at regular intervals. The unit masks 120 can be combined when led in the body member 110. Penetration portions 121 are formed in the unit masks 120. The size of the penetration portion 121 corresponds to a pixel formed on a substrate (not shown). A general organic light emitting diode (OLED) display device expresses colors with a group of a green light emitting pixel, a blue light emitting pixel, and a red light emitting pixel, and the size of the penetration portion 121 corresponds to each light emitting pixel.

Here, the organic light emitting diode (OLED) display device has been described to express colors with a group of a green light emitting pixel, a blue light emitting pixel, and a red light emitting pixel, which is an assumption for better understanding and ease of description, so it is also possible to add a white light emitting pixel to the group depending on the design.

The penetration portions 121 can be formed in the unit mask 120. The penetration portions 121 are patterned to be formed. The patterned penetration portions 121 are formed to have fine patterns and surface flatness by an electroforming method. The penetration portions 121 are manufactured by an etching method or a laser process. When the penetration portions 121 are manufactured by the etching method, they can be manufactured by using a photoresist and forming a resist layer having the same pattern as the penetration portions 121 on a thin plate or by attaching a film with a pattern to a thin plate and etching the thin plate.

A welding method is usable as an example for the method for fixing a plurality of unit masks 120 to the body member 110. The welding method has a merit of not increasing a thickness of the mask structure 100 according to the embodiment of the present invention compared to a method of using a fastening member such as a bolt or a pin.

To perform a high-precision patterning process by using the unit mask 120, a close contacting property between the unit mask 120 and the substrate (not shown) must be increased to reduce a shadow phenomenon. Therefore, it is desirable to form the unit mask 120 as a thin plate. Stainless steel, invar, nickel (Ni), cobalt (Co), a nickel alloy, and a nickel-cobalt alloy are usable for the material of the unit mask 120.

As an example of a shape of a plurality of unit masks 120, a plate may be formed to have a stick shape and may be disposed to cross the body member 110. For example, the unit mask 120 can be formed to cross the X direction of the body member 110, and can be disposed in parallel with the Y direction.

The above-configured mask structure 100 reduces the sagging caused by self-gravitation compared to the conventional mask configured with a single member, thereby preventing the shadow phenomenon caused by a gap between the mask structure 100 and the substrate. Therefore, the pixel (pattern) is formed on the accurate position of the substrate.

Further, regarding the mask structure 100, a plurality of unit masks 120 are separated by a width of the penetration portion having a size that corresponds to the pixel, thereby preventing overlapping of one pixel over an adjacent pixel when the pixel is deposited to the substrate. A detailed description thereof will be given later.

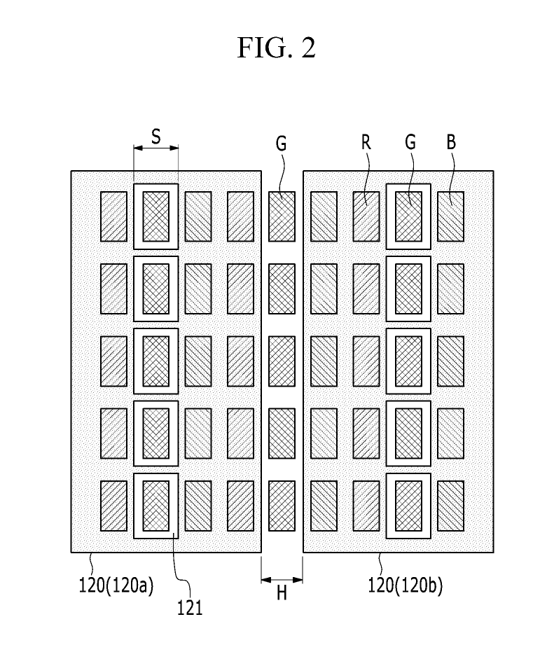

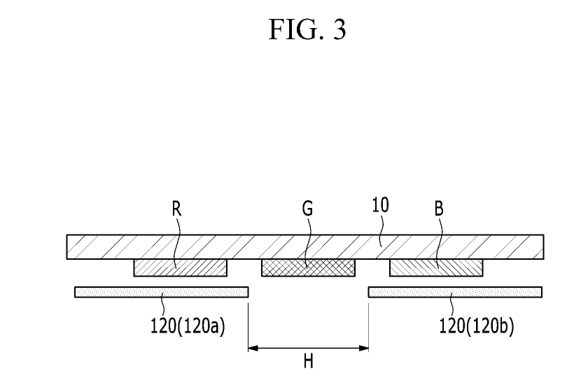

FIG. 2 shows a state in which a pixel is formed by a unit mask shown in FIG. 1, and FIG. 3 shows a cross-sectional view of a state in which a pixel is formed by a unit mask shown in FIG. 2.

Referring to FIG. 2 and FIG. 3, regarding the mask structure 100, penetration portions 121 that penetrate with a size that corresponds to a sub-pixel of a display device can be patterned in the unit masks 120. It is desirable to separately dispose the unit masks 120 by a width S of the penetration portion 121. That is, one unit mask 120a and an adjacent unit mask 120b are separated from each other by a specific length H.

For example, a display device manufactured by using the mask structure 100 is an organic light emitting diode (OLED) display device, and the organic light emitting diode (OLED) display device can include pixels in which a plurality of sub-pixels configure a group and express various colors in each. The sub-pixels that output red, green, and blue can be grouped to form a pixel. However, one pixel is not restricted to be configured with three sub-pixels. Regarding the mask structure 100, the penetration portion 121 formed in the unit masks 120 penetrates with a size that corresponds to the sub-pixel.

In this instance, when the gap between the sub-pixels of the organic light emitting diode (OLED) display device is 2 μm to 3 μm, the width S of the penetration portion 121 can be set to be substantially 2 μm to 3 μm and the gap H of the unit masks 120a and 120b can be set to be 2 μm to 3 μm, which prevents deposition of an organic material to the adjacent pixel when the pixel is formed on the substrate by the mask structure 100, and which forms the pixel at a specific position of the substrate 10.

That is, straightness is acquired and the shadow is minimized when the organic material is deposited on the substrate 10 by the above-configured mask structure 100 (refer to FIG. 1). Therefore, as shown in FIG. 3, while the blue light emitting pixel B and the red light emitting pixel R are formed on the substrate 10, the green light emitting pixel G is formed at a specific position of the substrate through the penetration portion 121 of the unit mask 120 of the mask structure 100, and the green light emitting pixel G does not intrude on the blue light emitting pixel B or the red light emitting pixel R.

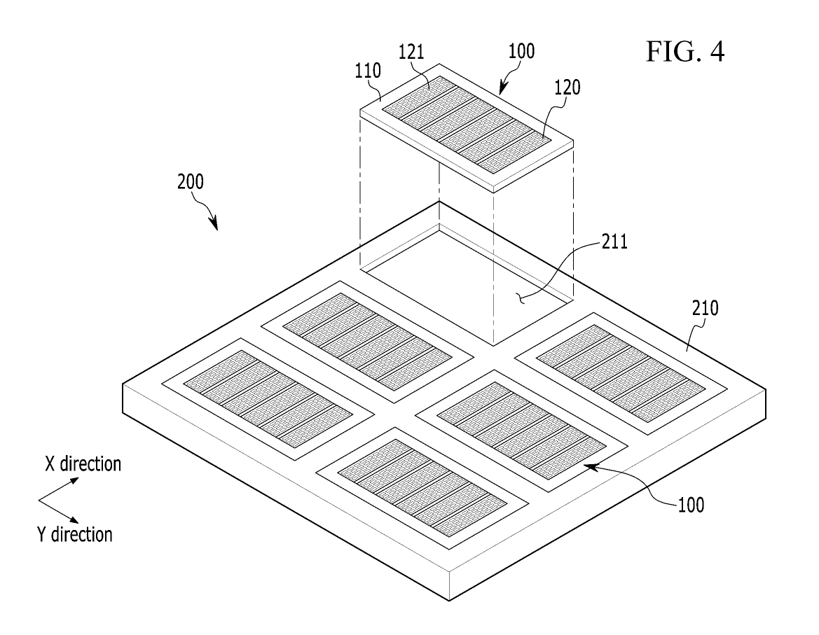

FIG. 4 shows a perspective view of a mask assembly according to an exemplary embodiment of the present invention.

Referring to FIG. 4, the mask assembly 200 includes an above-described mask structure 100 and a frame member 210.

The description of the mask structure 100 will be omitted.

A plurality of receivers 211 can be formed on the frame member 210. Each mask structure 100 is received in a receiver 211. Each receiver 211 can be formed to have a size that corresponds to the size of the body member 110 of the mask structure 100. For example, the receiver 211 can be formed to have the same size as the body member 110. Differing from this, the receiver 211 can be formed to be a little larger than the body member 110.

The receiver 211 can be formed on the frame member 210 according to a specific array. For example, as shown in FIG. 4, three receivers 211 can be formed in the X direction of the frame member 210 and two receivers 211 can be formed in the Y direction so six receivers 211 are formed. In addition, the receivers 211 are not restricted to be formed on the frame member 210 according to the above-noted array, and the array depends on the design.

A plurality of mask structures 100 are disposed on the frame member 210 to realize a larger mask assembly 200 so the organic material is deposited on the surface of the large substrate. For example, six mask structures each of which is 1200 mm×680 mm are used to realize a mask assembly with dimensions of 2500 mm×2200 mm. Accordingly, a greater quantity of panels can be produced per unit time, thereby improving productivity.

A method for manufacturing the above-described mask structure according to an exemplary embodiment of the present invention will now be described

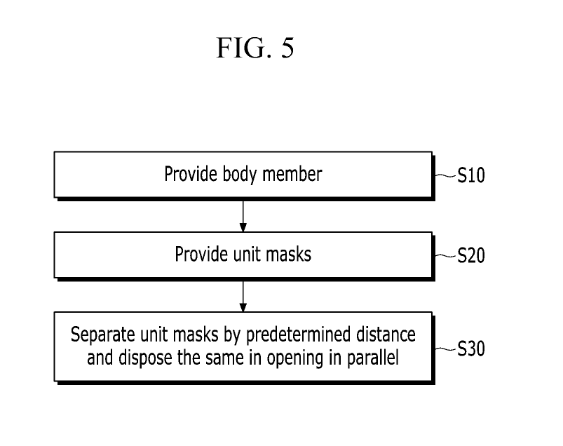

FIG. 5 shows a flowchart of a method for manufacturing a mask assembly according to an exemplary embodiment of the present invention.

Referring to FIG. 5, the method for manufacturing a mask assembly includes: providing the body member (S 10); providing the plurality of unit masks (S20); and separating the unit masks by regular intervals and disposing the unit masks in the opening in parallel with each other (S30).

The providing of the plurality of unit masks S20 includes forming penetration portions in the unit masks. Various methods such as the etching method or the laser process are usable for forming the penetration portions in the mask as described.

The separating of the unit masks at regular intervals and disposing of the unit masks in the opening in parallel with each other S30 includes separating the unit masks by a distance that is the same as a width of the penetration portion and disposing the same in the opening in parallel with each other.

In further detail, one of the unit masks is led and is combined to the opening through welding. Another unit mask is led with a predetermined gap from the unit mask and it is combined to the opening through welding, which is repeated. Here, the separation distance of the unit masks can be the same as the width of the penetration portion.

When the penetration portions are formed in the unit masks, the penetration portions are formed with a size that corresponds to the sub-pixel of the display device.

When the gap of the sub-pixel of the organic light emitting diode (OLED) display device is 2 μm, the width of the penetration portion is formed to be 2 μm. Respective gaps between the unit masks can be formed to be 2 μm.

The drawings and detailed description herein are to be construed as merely illustrative and not a limitation of the scope of the present invention as seen in the appended claims. Therefore, it will be appreciated by those skilled in the art that various modifications may be made and other equivalent embodiments are available. Accordingly, the actual scope of the present invention must be determined by the spirit of the appended claims.

What is claimed is:

1. A mask structure, comprising:
a body member in which an opening is formed; and
a plurality of unit masks disposed in parallel in the opening, and separated from each other by a predetermined distance.

2. The mask structure of claim 1, wherein penetration portions are formed in the unit masks, and the unit masks are separately disposed by a width of the penetration portions.

3. The mask structure of claim 1, wherein the unit masks are formed with a plate-type stick shape and are disposed to cross the body member.

4. The mask structure of claim 2, wherein the penetration portions of the unit masks are formed to have a size that corresponds to a sub-pixel of a display device.

5. A mask assembly, comprising:
a frame member on which a plurality of receivers are formed; and
a mask structure disposed in the receivers, the mask structure comprising:
a body member in which an opening is formed; and
a plurality of unit masks disposed in parallel in the opening, and separated from each other by a predetermined distance.

6. A method for manufacturing a mask structure, comprising:
providing a body member;
providing unit masks; and
separating the unit masks by a predetermined distance and disposing the unit masks in parallel in an opening of the body member.

7. The method of claim 6, wherein the providing the unit masks includes forming penetration portions in the unit masks, and the separating the unit masks by a predetermined distance includes separating the unit masks by a distance that is the same as the width of the penetration portion.

8. The method of claim 7, wherein the forming penetration portions in the unit masks includes forming the penetration portions with a size that corresponds to the sub-pixel of a display device.
